(19) United States
(12) Patent Application Publication
(10) Pub. No.: US 2025/0159909 A1
(43) Pub. Date: May 15, 2025

(54) MEMORY DEVICE AND METHOD OF FORMING THE SAME

(71) Applicant: Taiwan Semiconductor Manufacturing Company, Ltd., Hsinchu (TW)

(72) Inventors: Hengyuan Lee, Hsinchu County (TW); Xinyu BAO, Fremont, CA (US)

(73) Assignee: Taiwan Semiconductor Manufacturing Company, Ltd., Hsinchu (TW)

(21) Appl. No.: 18/510,595

(22) Filed: Nov. 15, 2023

(51) Int. Cl. H10B 63/00

(52) U.S. Cl. CPC H10B 63/845; H10B 63/24

(57) ABSTRACT

Provided are a memory device and a method of forming the same. The memory device includes a substrate, a stack structure, a bit line, and a selector layer. The stack structure is disposed over a substrate. The stack structure at least includes a data storage layer vertically sandwiched between a word line and a metal layer. The bit line penetrates through the stack structure. The selector layer laterally surrounds a sidewall of the bit line and contacts the metal layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, a three-dimensional (3D) memory device has been introduced to replace a planar memory device. However, 3D memory device has not been entirely satisfactory in all respects, additional problems arise that should be addressed.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIGS. 1, 2, 3, 4A, 4B, 5, 6, 7, 8, 9, and 10 illustrate cross-sectional views and top views of intermediate stages in the formation of a memory device in accordance with some embodiments.

FIG. 11 illustrates a cross-sectional view of a memory device in accordance with some alternative embodiments.

FIG. 12 illustrates a cross-sectional view of a memory device in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the Figures The spatially relative terms are intended to encompass different orientations of the device in use or operation in addition to the orientation depicted in the Figures The apparatus may be otherwise oriented (rotated 90 degrees or at other orientations) and the spatially relative descriptors used herein may likewise be interpreted accordingly.

The resistive random-access memory (RRAM) may include a bottom electrode, a top electrode overlying the bottom electrode, and a single dielectric layer between the bottom and top electrodes. The single dielectric layer comprises a metal oxide and has a single material composition throughout. During a set operation, a set voltage with a positive polarity is applied from the top electrode to the bottom electrode to form a conductive filament in the single dielectric layer. The conductive filament electrically couples the bottom electrode to the top electrode, such that the RRAM cell is in a low resistance state (LRS). During a reset operation, a reset voltage with a negative polarity is applied from the top electrode to the bottom electrode to at least partially dissolve the conductive filament. As such, the RRAM cell is in a high resistance state (HRS). Because a resistance of the RRAM cell changes during the set and reset operations, the resistance may be employed to represent a bit of data. For example, the LRS may represent a binary “1”, whereas the HRS may represent a binary “0”, or vice versa.

In accordance with some embodiments, a memory device includes a metal layer between a data storage layer and a selector layer to provide a lowest resistance path that not passing through an interface between the data storage layer and the selector layer. In this case, the material elements in the data storage layer and the selector layer do not diffuse into each other during the operation. That is, the elemental composition of the data storage layer and the selector layer may be maintained to enhance the reliability and the endurance of the memory device. Further, the data storage layer and the metal layer may be designed or formed individually to meet the design requirements, thereby increasing the design flexibility.

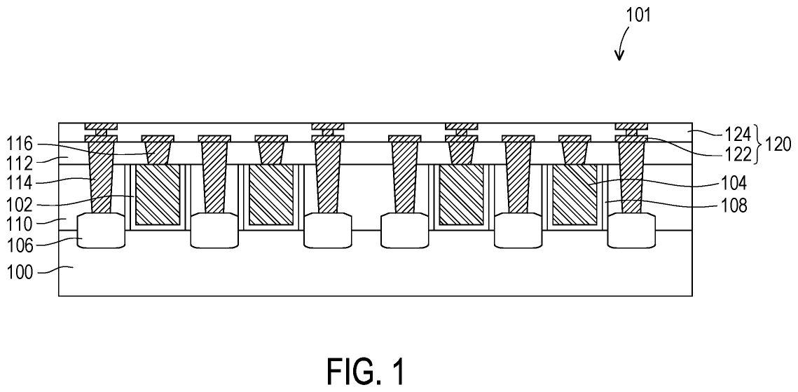

FIGS. 1, 2, 3, 4A, 4B, 5, 6, 7, 8, 9, and 10 illustrate cross-sectional views and top views of intermediate stages in the formation of a memory device in accordance with some embodiments.

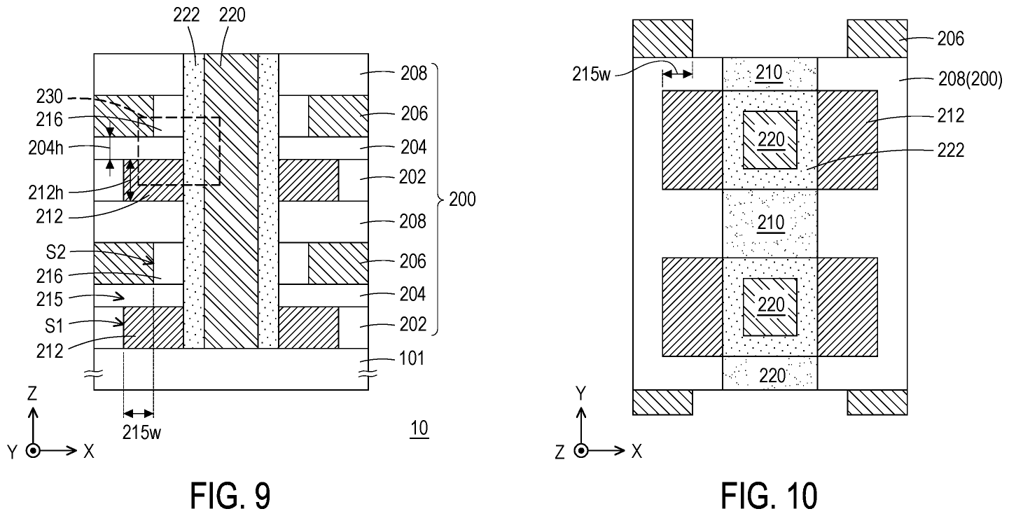

Referring to FIG. 1, a method of forming a semiconductor device 10 having a plurality of memory cells 230 (as shown in FIG. 9) includes following steps. First, an initial structure 101 illustrated in FIG. 1 is provided. The initial structure includes a substrate 100. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be an integrated circuit die, such as a logic die, a memory die, an ASIC die, or the like. The substrate 100 may be a complementary metal oxide semiconductor (CMOS) die and may be referred to as a CMOS under array (CUA). The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The initial structure 101 further includes circuits that may be formed over the substrate 100. The circuits include transistors at a top surface of the substrate 100. The transistors may include gate dielectric layers 102 over top surfaces of the substrate 100 and gate electrodes 104 over the gate dielectric layers 102. Source/drain regions 106 are disposed in the substrate 100 on opposite sides of the gate dielectric layers 102 and the gate electrodes 104. Gate spacers 108 are formed along sidewalls of the gate dielectric layers 102 and separate the source/drain regions 106 from the gate electrodes 104 by appropriate lateral distances. The transistors may include fin field effect transistors (FinFETs), nanostructure (e.g., nanosheet, nanowire, gate-all-around, or the like) FETS (nano-FETs), planar FETs, the like, or combinations thereof, and may be formed by gate-first processes or gate-last processes.

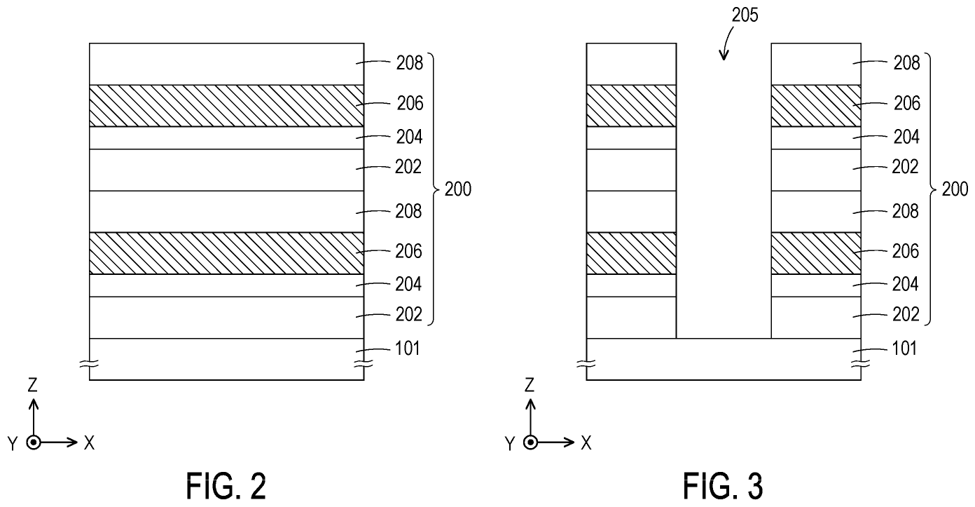

A first inter-layer dielectric (ILD) 110 surrounds and isolates the source/drain regions 106, the gate dielectric layers 102, and the gate electrodes 104 and a second ILD 112 is over the first ILD 110. Source/drain contacts 114 extend through the second ILD 112 and the first ILD 110 and are electrically coupled to the source/drain regions 106 and gate contacts 116 extend through the second ILD 112 and are electrically coupled to the gate electrodes 104. A first interconnect structure 120 is over the second ILD 112, the source/drain contacts 114, and the gate contacts 116. The first interconnect structure 120 includes one or more stacked dielectric layers (e.g., inter-metal dielectric (IMD) layer) 124 and conductive features (e.g., conductive lines and vias) 122 formed in the one or more dielectric layers 124, for example. The first interconnect structure 120 may be electrically connected to the gate contacts 116 and the source/drain contacts 114 to form functional circuits. In some embodiments, the functional circuits formed by the first interconnect structure 120 may include logic circuits, memory circuits, sense amplifiers, controllers, input/output circuits, image sensor circuits, the like, or combinations thereof. Although FIG. 1 discusses transistors formed over the substrate 100, other active devices (e.g., diodes or the like) and/or passive devices (e.g., capacitors, resistors, or the like) may also be formed as part of the functional circuits. The initial structure 101 illustrated in FIG. 1 may be referred to as an underlying structure 101, and the components of the underlying structure 101 illustrated in FIG. 2 are omitted for clarity.

Referring to FIG. 2, after forming the underlying structure 101, a stack structure 200 is formed over the underlying structure 101. Specifically, the stack structure 200 from bottom to top includes a first dielectric layer 202, a data storage layer 204, a conductive layer 206, and a second dielectric layer 208. That is, the first dielectric layer 202, the data storage layer 204, the conductive layer 206, and the second dielectric layer 208 are stacked alternately along the Z direction.

In some embodiments, the first dielectric layer 202 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the first dielectric layer 202 includes low-k dielectric materials. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In alternative embodiments, the first dielectric layer 202 include one or more dielectric materials. In some embodiments, the first dielectric layer 202 is formed by any suitable method, such as CVD, spin-on, or the like.

The data storage layer 204 may include a variable resistive material. In some embodiments, the variable resistive material has a resistance conversion characteristic (e.g., variable resistance). In detail, the variable resistive material may include material characterized to show reversible resistance variance in accordance with a polarity and/or an amplitude of an applied electrical pulse. The variable resistive material includes a dielectric layer which is changed into a conductor or an insulator based on polarity and/or magnitude of electrical signal.

In one embodiment, the variable resistive material may include a transition metal oxide. The transition metal oxide may be denoted as MxOy where M is a transition metal, O is oxygen, x is the transition metal composition, and y is the oxygen composition. In an embodiment, the variable resistive material includes ZrO₂. Examples of other materials suitable for the variable resistive material include: NiO, TiO₂, HfO, ZrO, ZnO, WO₃, CoO, Nb₂O₅, Fe₂O₃, CuO, CrO₂, SrZrO₃ (Nb-doped), and/or other materials known in the art. In another embodiment, the variable resistive material may include a colossal magnetoresistance (CMR)-based material such as, for example, Pr_{0.7}Ca_{0.3}, MnO₃, etc.

In yet another embodiment, the variable resistive material may include a polymer material, such as polyvinylidene fluoride and poly [(vinylidenefluoride-co-trifluoroethylene] (P(VDF/TrFE)), for example. In yet another embodiment, the variable resistive material may include a conductive-bridging random access memory (CBRAM) material, such as Ag in GeSe, for example. According to some embodiments, the variable resistive material may include multiple layers having characteristics of a resistance conversion material. A set voltage and/or a reset voltage of the variable resistive material may be determined by the variable resistive material's compositions, thickness, and/or other factors known in the art.

In some embodiments, the data storage layer 204 may be formed by an atomic layer deposition (ALD) technique with a precursor containing a metal and oxygen. In some embodiments, other chemical vapor deposition (CVD) techniques may be used. In some embodiments, the data storage layer 204 may be formed by a physical vapor deposition (PVD) technique, such as a sputtering process with a metallic target and with a gas supply of oxygen and optionally nitrogen to the PVD chamber. In some embodiments, the data storage layer 204 may be formed by an electron-beam deposition technique.

In some embodiments, the conductive layer 206 may include Ti, Co, Cu, AlCu, W, TIN, TiW, TiAl, TiAlN, Ru, RuOₓ, or a combination thereof, and may be formed by any suitable method, such as CVD, PVD, ALD, or the like. In the embodiment, the conductive layer 206 may be patterned to be used as the word line.

In some embodiments, the second dielectric layer 208 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the second dielectric layer 208 includes low-k dielectric materials. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In alternative embodiments, the second dielectric layer 208 include one or more dielectric materials. In some embodiments, the second dielectric layer 208 is formed by any suitable method, such as CVD, spin-on, or the like.

In the present embodiment, the second dielectric layer 208 and the first dielectric layer 202 have different materials with different etch selectivities. For example, the first dielectric layer 202 may be made of silicon oxide, and the second dielectric layer 208 may be made of silicon nitride.

Although FIG. 2 illustrates two layers of the first dielectric layers 202, two layers of the data storage layers 204, two layers of the conductive layers 206, and two layers of the second dielectric layers 208. However, it should be appreciated that the stack structure 200 may include any number of the first dielectric layer 202, the data storage layer 204, the conductive layer 206, and the second dielectric layer 208.

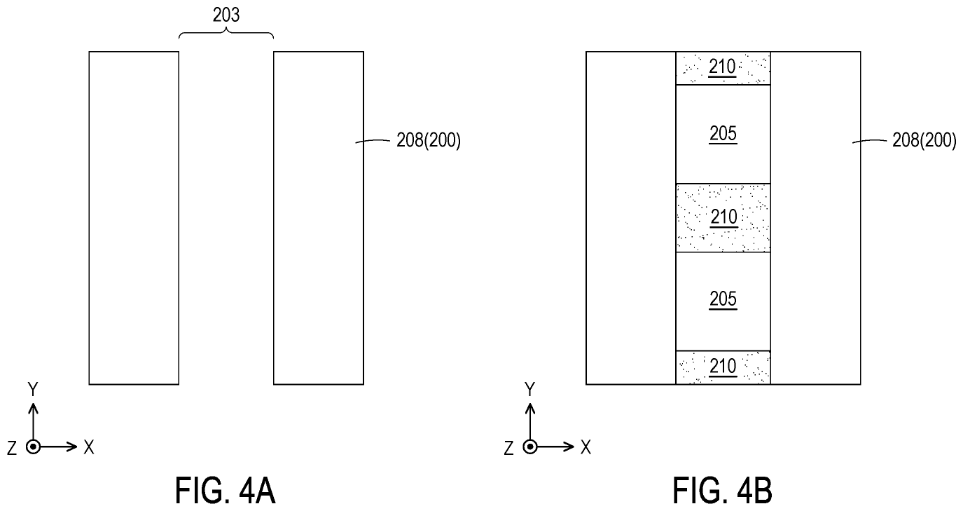

Referring to FIG. 3, an opening 205 is formed in the stack structure 200 to expose sidewalls of the first dielectric layer 202, the data storage layer 204, the conductive layer 206, and the second dielectric layer 208. In detail, the opening 205 may be formed by following steps. First, as shown in the top view of FIG. 4A, a trench 203 may be formed in the stack structure 200. The trench 203 may extend along the Y direction and penetrate through the stack structure 200 along the Z direction. After forming the trench 203, an insulating material 210 may be formed to fill in the trench 203, as shown in the top view of FIG. 4B. In some embodiments, the insulating material 210 includes silicon oxide, silicon nitride, silicon oxynitride, PSG, BPSG, SOG, FSG, carbon doped silicon oxide (e.g., SiCOH), polyimide, and/or a combination thereof. The insulating material 210 may be formed by any suitable method, such as CVD, spin-on, or the like. In the present embodiment, the insulating material 210 and the first dielectric layer 202 have different materials with different etch selectivities. For example, the first dielectric layer 202 may be made of silicon oxide, and the insulating material 210 may be made of silicon nitride. After forming the insulating material 210, the opening 205 may be formed in the insulating material 210. In some embodiments, the insulating material 210 and the openings 205 may be arranged alternately along the Y direction, as shown in the top view of FIG. 4B.

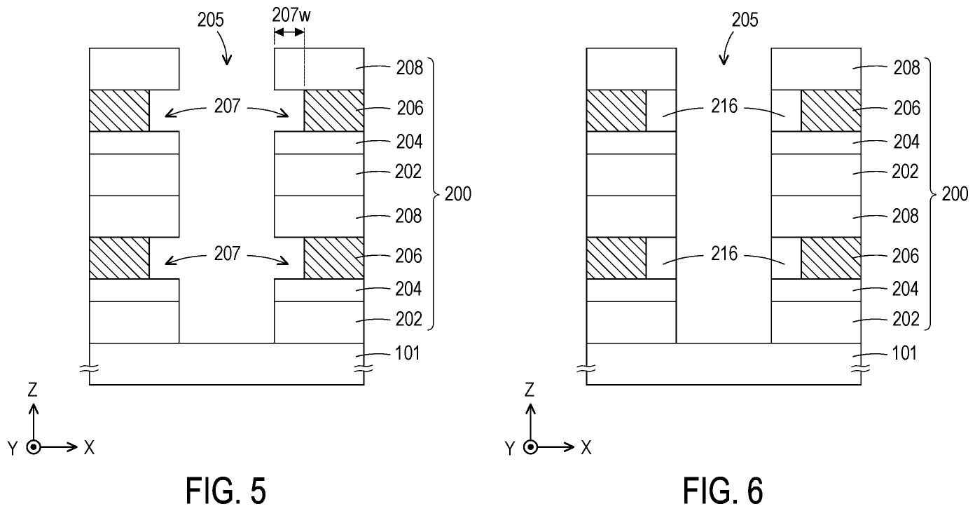

Referring to FIG. 5, the sidewall of the conductive layer 206 may be laterally etched to form a first recess 207 among the conductive layer 206, the data storage layer 204, and the second dielectric layer 208. Specifically, an etching process may be performed to remove a portion of the conductive layer 206 through the opening 205. It should be noted that, in the present embodiment, the conductive layer 206 has the material with different etching selectivities from the other layers 202, 204, and 208 in the etching process. Therefore, the portion of the conductive layer 206 is removed, while the other layers 202, 204, and 208 are not removed or only a small amount of the other layers 202, 204, and 208 is removed. In this case, the first recess 207 may be formed between the data storage layer 204 and the second dielectric layer 208. That is, the sidewall of the conductive layer 206 may be recessed from the opening 205, and the sidewall of the conductive layer 206 is not aligned with the sidewalls of the other layers 202, 204, and 208. In some embodiments, the first recess 207 has a lateral width 207w of 1 nm to 1 μm.

Referring to FIG. 6, a third dielectric layer 216 may be formed in the first recess 207. Specifically, a dielectric material may be formed to cover a top surface of the stack structure 200, a sidewall of the opening 205, a top surface of the underlying structure 101, and fill into the first recess 207. Next, an etching process is performed to remove the dielectric material on the top surface of the stack structure 200, the sidewall of the opening 205, and the top surface of the underlying structure 101, so that the remaining portion of the dielectric material filled in the first recess 207 forms the third dielectric layer 216. In this case, the third dielectric layer 216 may have a sidewall substantially aligned with the sidewalls of the first dielectric layer 202, the data storage layer 204, and the second dielectric layer 208. In some embodiments, the third dielectric layer 216 includes silicon oxide, silicon nitride, silicon oxynitride, PSG, BPSG, SOG, FSG, carbon doped silicon oxide (e.g., SiCOH), polyimide, and/or a combination thereof. The third dielectric layer 216 may be formed by any suitable method, such as CVD, spin-on, or the like. In the present embodiment, the third dielectric layer 216 and the second dielectric layer 208 have the same material. For example, the third dielectric layer 216 and the second dielectric layer 208 may be made of silicon nitride.

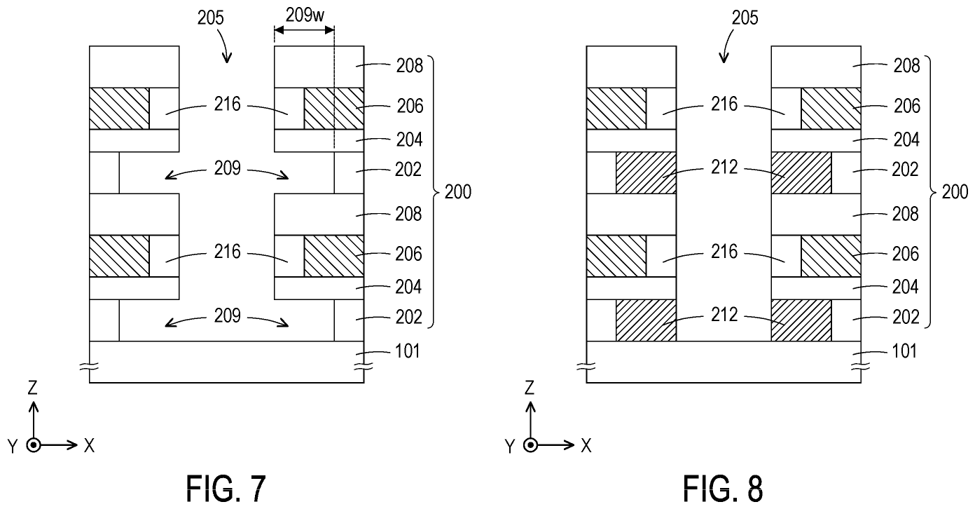

Referring to FIG. 7, the sidewall of the first dielectric layer 202 may be laterally etched to form a second recess 209 among the first dielectric layer 202, the data storage layer 204, and the second dielectric layer 208. Specifically, an etching process may be performed to remove a portion of first dielectric layer 202 through the opening 205. It should be noted that, in the present embodiment, the first dielectric layer 202 has the material with different etching selectivities from the other layers 204, 216, 208, and 210 (FIG. 4B) in the etching process. Therefore, the portion of the first dielectric layer 202 is removed, while the other layers 204, 216, 208, and 210 are not removed or only a small amount of the other layers 204, 216, 208, and 210 is removed. In this case, the second recess 209 is formed among the first dielectric layer 202, the data storage layer 204, and the second dielectric layer 208. In this case, the sidewall of the second recess 209 is recessed from the opening 205, and the sidewall of the first dielectric layer 202 is not aligned with the sidewalls of the other layers 204, 216, and 208. In some embodiments, the second recess 209 has a lateral width 209w of 1 nm to 1 μm. In the embodiment, the lateral width 209w of the second recess 209 is substantially greater than the lateral width 207w of the first recess 207 (FIG. 5).

Referring to FIG. 8, a metal layer 212 may be formed in the second recess 209. Specifically, a metal material may be formed to cover the top surface of the stack structure 200, the sidewall of the opening 205, the top surface of the underlying structure 101, and fill into the second recess 209. Next, an etching process is performed to remove the metal material on the top surface of the stack structure 200, the sidewall of the opening 205, and the top surface of the underlying structure 101, so that the remaining portion of the metal material filled in the second recess 209 forms the metal layer 212. In this case, the metal layer 212 may have a sidewall substantially aligned with the sidewalls of the data storage layer 204, the third dielectric layer 216, and the second dielectric layer 208. In some embodiments, the metal layer 212 includes the metal material, such as tungsten, ruthenium, molybdenum, cobalt, aluminum, nickel, copper, silver, gold, alloys thereof, or the like. The metal layer 212 may be formed by an acceptable deposition process such as CVD, PVD, ALD, PECVD, or the like.

Referring to FIG. 9, a conductive pillar 220 and a selector layer 222 may be formed in the opening 20. In detail, a selector material may be formed to conformally cover the top surface of the stack structure 200, the sidewall of the opening 205, and the top surface of the underlying structure 101. Next, an etching process is performed to remove the selector material on the top surface of the stack structure 200 and the top surface of the underlying structure 101, so that the remaining portion of the selector material covering the sidewall of the opening 205 forms the selector layer 222. Then, a conductive material is formed to fill in the opening 205 surrounding by the selector layer 222, and the excess conductive material from the top surface of the stack structure 200 is removed to form the conductive pillar 220. In this case, a sidewall of the conductive pillar 220 is laterally surrounded by the selector layer 222. In the present embodiment, the selector layer 222 completely surrounds the sidewall of the conductive pillar 220, as shown in the top view of FIG. 10.

In some embodiments, the selector layer 222 may include an ovonic threshold switch (OTS) material, which is a two-terminal symmetrical voltage sensitive switching device and may be characterized before it is used in a circuit device. The OTS mechanism includes in a switch between a high resistive (OFF state) at a low electric field and a low resistive state (ON state) when a specific voltage is obtained. For example, when an applied voltage that is less than a threshold voltage is applied one the selector layer 222, the selector layer 222 remains in an “off” state, e.g., an electrically nonconductive state. Alternatively, responsive to an applied voltage across the selector layer 222 that is greater than the threshold voltage, the selector layer 222 enters an “on” state, e.g., an electrically conductive state. That is, the selector layer 222 is referred to as a switch for determining to turn on or turn off the memory pillars 200. As such, the OTS may allow for bidirectional switching and may be easily integrated as a select device for a memory device.

In some embodiments, the selector layer 222 may be a binary OTS material such as TeC, TeB, GeSe, a ternary OTS material such as GeCTe, AsGeSe, GeSeN, GeSeTe, or GeSeSi, a quaternary OTS material such as TeAsGeSe, SiAsGeSe, or SiGeAsTe, a quinary OTS material such as SiTeAsGeSe, STeAsGeSe, or BTeAsGeSe, a senary OTS material such as BSiTeAsGeSe, a septenary OTS material such as NBSiTeAsGeSe, an octonary OTS material such as SNBSiTeAsGeSe, or other suitable materials. However, the embodiments of the present disclosure are not limited thereto. In other embodiments, other materials that can provide switching characteristics also be candidates for the material of the selector. Although the selector layer 222 illustrated in FIG. 9 is a single-layered structure, the embodiments of the present disclosure are not limited thereto. In some alternative embodiments, the selector layer 222 may be a bi-layered or multi-layered structure. In such embodiment, the selector layer 222 having the bi-layered or multi-layered structure may be designed to concentrate the passing current, thereby improving the switching performance.

In some embodiments, the conductive pillar 220 may include Ti, Co, Cu, AlCu, W. TIN, TiW. TiAl, TiAlN, Ru, RuOₓ, or a combination thereof, and may be formed by any suitable method, such as CVD, PVD, ALD, or the like. In the embodiment, the conductive pillar 220 may be referred to as the bit line.

As shown in FIG. 9 and FIG. 10, after forming the conductive pillar 220 and the selector layer 222, a memory device 10 is accomplished. Specifically, the memory device 10 may include the stack structure 200, the conductive pillar 220 (hereinafter called bit line), and the selector layer 222. The stack structure 200 may be disposed over underlying structure 101. The stack structure 200 may include the first dielectric layer 202, the data storage layer 204, the conductive layer 206 (hereinafter called word line), the second dielectric layer 208, the metal layer 212, and the third dielectric layer 216. The first dielectric layer 202 may be disposed aside the metal layer 212. In some embodiments, the first dielectric layer 202 and the metal layer 212 are located at the same level and have the same thickness. The data storage layer 204 may be disposed on and/or in contact with the first dielectric layer 202 and the metal layer 212. The word line 206 and the third dielectric layer 216 may be disposed on and/or in contact with the data storage layer 204. The word line 206 may be disposed aside the third dielectric layer 216. In some embodiments, the word line 206 and the third dielectric layer 216 are located at the same level and have the same thickness. The bit line 220 may penetrate through the stack structure 200, and the selector layer 222 may laterally surround the sidewall of the bit line 220. In some embodiments, the selector layer 222 is sandwiched between the sidewall of the stack structure 200 and the bit line 220 along the X direction. In detail, the selector layer 222 may have an outer sidewall in contact with the data storage layer 204, the second dielectric layer 208, the metal layer 212, and the third dielectric layer 216; and an inner sidewall in contact with the bit line 220.

From another point of view, the memory device 10 may include a plurality of memory cells 230. Specifically, one of the memory cells 230 may include a portion of the data storage layer 204, a portion of the word line 206, a portion of the metal layer 212, a portion of the bit line 220, and a portion of the selector layer 222. The data storage layer 204 may be vertically sandwiched between and in contact with the word line 206 and the metal layer 212. The word line 206 may be separated from the selector layer 222 by the third dielectric layer 216. The selector layer 222 may be laterally sandwiched between and in contact with the bit line 220 and the metal layer 212. In this case, the memory device 10 operates under the principle that the data storage layer 204, which is normally insulating, can be made to conduct through a filament or conduction path formed after the application of a sufficiently high voltage. The conduction path formation can arise from different mechanisms, including but not limited to defect, metal migration, oxygen vacancy, etc. As described above, during a write operation to the memory cell 230, a “set” voltage is applied across the data storage layer 204 to change the variable resistive material of the data storage layer 204 from a first resistivity (e.g., a high resistance state (HRS), where a filament or conduction path in the data storage layer 204 is broken) to a second resistivity (e.g., a low resistance state (LRS), where the filament or conduction path in the data storage layer 204 is established).

Similarly, a “reset” voltage is applied across the data storage layer 204 to change the variable resistive material of the data storage layer 204 from the second resistivity back to the first resistivity, for example, from LRS to HRS. Therefore, in instances where the LRS and HRS correspond to logic “1” and logic “0” states (or vice versa), respectively; the “set” and “reset” voltages can be used to store digital information bits in the memory device 10 through the memory cell 230 to provide relevant memory functions.

In some embodiments, the data storage layer 204 is in contact with and electrically connected to the selector layer 222 through the metal layer 212 (which simultaneously serving the electrode of the memory cell 230 and the connecting structure). That is, the data storage layer 204 is electrically coupled to the selector layer 222 in series. With such configuration, the voltage may be applied to the selector layer 222 for controlling the status (e.g., “on” or “off”) of the memory cell 230. While the memory cell 230 is turned on, the voltages are further applied to the metal layer 212 of the memory cell 230 for operating the memory functions thereof (via HRS and LRS). The control mechanism of the selector layer 222 and the operating principle of the memory cell 230 have been described in the above, and thus are omitted herein for simplicity. In such embodiment, all of the memory cells 230 share the same selector layer 222 to form one selector-one resistor (1S1R) configuration.

In some embodiment, the 1S1R configuration may be disposed between the metal n (Mn) and the metal n−1 (Mn−1). That is, the memory device 10 may be disposed between any two adjacent conductive layers in the back-end-of-line (BEOL) structure. For example, the memory device 10 is disposed between the metal 3 (M3) and the metal 4 (M4). In this case, the bit line 220 and the word line 206 are electrically coupled to the drivers (e.g., word line (WL) drivers and bit line (BL) drivers), the sense amplifiers, or the like through the underlying interconnect structure 120 (FIG. 1). Also, the memory device 10 may be disposed between the metal 4 (M4) and the metal 5 (M5), between the metal 5 (M5) and metal 6 (M6), and so on. Based on above, the fabricating process of the memory device 10 may be compatible with the BEOL process of the semiconductor device, thereby simplifying process steps and efficiently improving the integration density.

Although FIG. 9 illustrates four memory cells 230 respectively arranged at opposite sides of the bit line 220, the embodiments of the present disclosure are not limited thereto. In some alternative embodiments, the number of the memory cells 230 may be adjusted by the needs.

It should be noted that, in the present embodiment, a first projection of the word line 206 projected on the underlying structure 101 (or the substrate) at least partially overlaps a second projection of the metal layer 212 projected on the underlying structure 101. That is, the overlap portion 215 between the first projection of the word line 206 and the second projection of the metal layer 212 may have an overlap width 215w of 1 nm to 1 μm. Herein, the overlap width 215 may be measured from a first interface S1 between the first dielectric layer 202 and the metal layer 212 to a second interface S2 between the word line 206 and the third dielectric layer 216. In this case, the current will flow along the lowest resistance path, so that the filament or conduction path formed in the overlap portion 215 of the data storage layer 204. In the present embodiment, the lowest resistance path may include a path from the bit line 220 through the selector layer 222, the metal layer 212, and the overlap portion 215 of the data storage layer 204 to the word line 206. In addition, since current may not pass through the interface between the data storage layer 204 and the selector layer 222, the material elements in the data storage layer 204 and the selector layer 222 do not diffuse into each other during the operation of memory cells 230. That is, the elemental composition of the data storage layer 204 and the selector layer 222 may be maintained to enhance the reliability and the endurance of the memory device 10.

In the present embodiment, the data storage layer 204 has a thickness 204h different from a thickness 212h of the metal layer 212. That is, the data storage layer 204 and the metal layer 212 may be designed or formed individually to meet the design requirements, thereby increasing the design flexibility. In some embodiments, the thickness 204h of the data storage layer 204 may be in the range of 1 nm to 1 μm; and the thickness 212h of the metal layer 212 may be in the range of 1 nm to 1 μm.

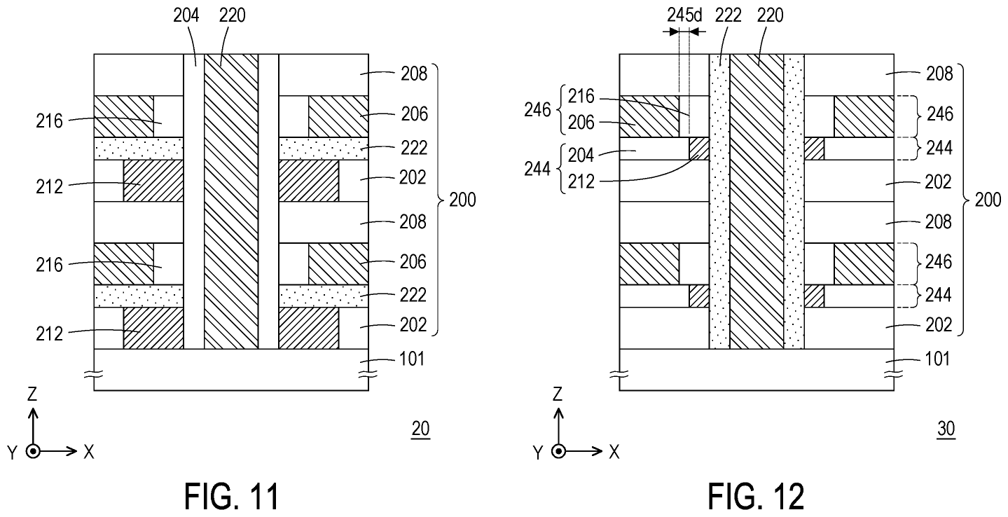

FIG. 11 illustrates a cross-sectional view of a memory device in accordance with some alternative embodiments.

Referring to FIG. 11, a memory device 20 is similar to the memory device 10 of FIG. 9. That is, the structures, materials, and functions of the memory device 20 are similar to those of the memory device 10, and thus the details are omitted herein. The main difference between the memory device 20 and the memory device 10 lies in that the positions of the data storage layer 204 and the selector layer 222 are swapped. Specifically, the memory device 20 may include the stack structure 200, the bit line 220, and the data storage layer 204. The stack structure 200 may be disposed over underlying structure 101. The stack structure 200 may include the first dielectric layer 202, the selector layer 222, the word line 206, the second dielectric layer 208, the metal layer 212, and the third dielectric layer 216. The first dielectric layer 202 may be disposed aside the metal layer 212. The selector layer 222 may be disposed on and/or in contact with the first dielectric layer 202 and the metal layer 212. The word line 206 and the third dielectric layer 216 may be disposed on and/or in contact with the selector layer 222. The word line 206 may be disposed aside the third dielectric layer 216. The bit line 220 may penetrate through the stack structure 200, and the data storage layer 204 may laterally surround the sidewall of the bit line 220. In some embodiments, the data storage layer 204 is sandwiched between the sidewall of the stack structure 200 and the bit line 220 along the X direction. In detail, the data storage layer 204 may have an outer sidewall in contact with the selector layer 222, the second dielectric layer 208, the metal layer 212, and the third dielectric layer 216; and an inner sidewall in contact with the bit line 220.

FIG. 12 illustrates a cross-sectional view of a memory device in accordance with some other embodiments.

Referring to FIG. 12, a memory device 30 is similar to the memory device 10 of FIG. 9. That is, the structures, materials, and functions of the memory device 30 are similar to those of the memory device 10, and thus the details are omitted herein.

Specifically, the memory device 30 may include the stack structure 200, the bit line 220, and the selector layer 222. The stack structure 200 may be disposed over underlying structure 101. The stack structure 200 may include the first dielectric layer 202, a variable resistive structure 244, a word line structure 246, the second dielectric layer 208. The variable resistive structure 244 may include a variable resistive layer 204 and a contact layer 212 aside the variable resistive layer 204. In some embodiments, the variable resistive layer 204 and the contact layer 212 are located at the same level and have the same thickness. The word line structure 246 may include the word line 206 and the third dielectric layer 216 aside the word line 206. In some embodiments, the word line 206 and the third dielectric layer 216 are located at the same level and have the same thickness. The word line 206 may be separated from the selector layer 222 by the third dielectric layer 216. The bit line 220 may penetrate through the stack structure 200, and the selector layer 222 may laterally surround the sidewall of the bit line 220. In some embodiments, the selector layer 222 is sandwiched between the sidewall of the stack structure 200 and the bit line 220 along the X direction. In detail, the selector layer 222 may have an outer sidewall in contact with the second dielectric layer 208, the contact layer 212, and the third dielectric layer 216; and an inner sidewall in contact with the bit line 220.

It should be noted that, in the present embodiment, a first projection of the word line 206 projected on the underlying structure 101 (or the substrate) is offset from a second projection of the contact layer 212 projected on the underlying structure 101 by a non-zero distance 245d to avoid the short between the word line 206 and the contact layer 212. In some embodiments, the non-zero distance 245d is in the range of 1 nm to 1 μm. In addition, since the variable resistive layer 204 may be separated from the selector layer 222 by the contact layer 212, the material elements in the variable resistive layer 204 and the selector layer 222 do not diffuse into each other during the operation. That is, the elemental composition of the variable resistive layer 204 and the selector layer 222 may be maintained to enhance the reliability and the endurance of the memory device 30.

In accordance with an embodiment, a memory device includes a stack structure disposed over a substrate, wherein the stack structure at least comprises a data storage layer vertically sandwiched between a word line and a metal layer; a bit line penetrating through the stack structure; and a selector layer laterally surrounding a sidewall of the bit line and contacting the metal layer.

In some embodiments, the selector layer completely surrounds the sidewall of the bit line and is in contact with the data storage layer. In some embodiments, a first projection of the word line projected on the substrate at least partially overlaps a second projection of the metal layer projected on the substrate. In some embodiments, the memory device further includes a first dielectric layer disposed aside the metal layer; and a second dielectric layer disposed aside the word line, wherein the second dielectric layer and the first dielectric layer have different materials with different etch selectivities. In some embodiments, the first dielectric layer and the metal layer are located at the same level and have the same thickness. In some embodiments, the second dielectric layer and the word line are located at the same level and have the same thickness. In some embodiments, the word line is separated from the selector layer by the second dielectric layer.

In accordance with an embodiment, a method of forming a memory device includes forming a stack structure over a substrate, wherein the stack structure sequentially comprises: a first dielectric layer, a data storage layer, a conductive layer, and a second dielectric layer; forming an opening in the stack structure to expose sidewalls of the first dielectric layer, the data storage layer, the conductive layer, and the second dielectric layer; laterally etching the sidewall of the conductive layer to form a first recess among the conductive layer, the data storage layer, and the second dielectric layer; forming a third dielectric layer in the first recess; laterally etching the sidewall of the first dielectric layer to form a second recess between the first dielectric layer and the data storage layer; forming a metal layer in the second recess; and forming a conductive pillar and a selector layer laterally surrounding a sidewall of the conductive pillar in the opening.

In some embodiments, the second dielectric layer and the first dielectric layer have different materials with different etch selectivities, and the second dielectric layer and the third dielectric layer have the same material. In some embodiments, the second recess has a lateral width substantially greater than a lateral width of the first recess. In some embodiments, a first projection of the conductive layer projected on the substrate at least partially overlaps a second projection of the metal layer projected on the substrate. In some embodiments, the selector layer completely surrounds the sidewall of the conductive pillar and is in contact with the metal layer. In some embodiments, a material of the data storage layer comprises a variable resistive material, and a material of the selector layer comprises an ovonic threshold switch (OTS) material. In some embodiments, the forming the opening in the stack structure comprises: forming a trench in the stack structure; filling in the trench with an insulating material; and forming the opening penetrating through the stack structure in the insulating material. In some embodiments, the insulating material and the first dielectric layer have different materials with different etch selectivities.

In accordance with an embodiment, a memory device includes a stack structure disposed over a substrate, wherein the stack structure at least comprises: a variable resistive structure comprising a variable resistive layer and a contact layer; and a word line structure disposed on the variable resistive structure; a bit line penetrating through the stack structure; and a selector layer laterally surrounding a sidewall of the bit line and contacting the contact layer.

In some embodiments, the variable resistive layer is separated from the selector layer by the contact layer. In some embodiments, the variable resistive layer and the contact layer are located at the same level and have the same thickness. In some embodiments, the word line structure comprises a word line and a dielectric layer aside the word line, and the word line is separated from the selector layer by the dielectric layer. In some embodiments, a first projection of the word line projected on the substrate is offset from a second projection of the contact layer projected on the substrate by a non-zero distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a stack structure disposed over a substrate, wherein the stack structure at least comprises a data storage layer vertically sandwiched between a word line and a metal layer;
a bit line penetrating through the stack structure; and
a selector layer laterally surrounding a sidewall of the bit line and contacting the metal layer.

2. The memory device of claim 1, wherein the selector layer completely surrounds the sidewall of the bit line and is in contact with the data storage layer.

3. The memory device of claim 1, wherein a first projection of the word line projected on the substrate at least partially overlaps a second projection of the metal layer projected on the substrate.

4. The memory device of claim 1, further comprising:
a first dielectric layer disposed aside the metal layer; and
a second dielectric layer disposed aside the word line, wherein the second dielectric layer and the first dielectric layer have different materials with different etch selectivities.

5. The memory device of claim 4, wherein the first dielectric layer and the metal layer are located at the same level and have the same thickness.

6. The memory device of claim 4, wherein the second dielectric layer and the word line are located at the same level and have the same thickness.

7. The memory device of claim 4, wherein the word line is separated from the selector layer by the second dielectric layer.

8. A method of forming a memory device, comprising:
forming a stack structure over a substrate, wherein the stack structure sequentially comprises: a first dielectric layer, a data storage layer, a conductive layer, and a second dielectric layer;
forming an opening in the stack structure to expose sidewalls of the first dielectric layer, the data storage layer, the conductive layer, and the second dielectric layer;
laterally etching the sidewall of the conductive layer to form a first recess among the conductive layer, the data storage layer, and the second dielectric layer;
forming a third dielectric layer in the first recess;
laterally etching the sidewall of the first dielectric layer to form a second recess between the first dielectric layer and the data storage layer;
forming a metal layer in the second recess; and
forming a conductive pillar and a selector layer laterally surrounding a sidewall of the conductive pillar in the opening.

9. The method of claim 8, wherein the second dielectric layer and the first dielectric layer have different materials with different etch selectivities, and the second dielectric layer and the third dielectric layer have the same material.

10. The method of claim 8, wherein the second recess has a lateral width substantially greater than a lateral width of the first recess.

11. The method of claim 8, wherein a first projection of the conductive layer projected on the substrate at least partially overlaps a second projection of the metal layer projected on the substrate.

12. The method of claim 8, wherein the selector layer completely surrounds the sidewall of the conductive pillar and is in contact with the metal layer.

13. The method of claim 8, wherein a material of the data storage layer comprises a variable resistive material, and a material of the selector layer comprises an ovonic threshold switch (OTS) material.

14. The method of claim 8, wherein the forming the opening in the stack structure comprises:
forming a trench in the stack structure;
filling in the trench with an insulating material; and
forming the opening penetrating through the stack structure in the insulating material.

15. The method of claim 14, wherein the insulating material and the first dielectric layer have different materials with different etch selectivities.

16. A memory device, comprising:
a stack structure disposed over a substrate, wherein the stack structure at least comprises:
a variable resistive structure comprising a variable resistive layer and a contact layer; and
a word line structure disposed on the variable resistive structure;
a bit line penetrating through the stack structure; and
a selector layer laterally surrounding a sidewall of the bit line and contacting the contact layer.

17. The memory device of claim 16, wherein the variable resistive layer is separated from the selector layer by the contact layer.

18. The memory device of claim 16, wherein the variable resistive layer and the contact layer are located at the same level and have the same thickness.

19. The memory device of claim 16, wherein the word line structure comprises a word line and a dielectric layer aside the word line, and the word line is separated from the selector layer by the dielectric layer.

20. The memory device of claim 19, wherein a first projection of the word line projected on the substrate is offset from a second projection of the contact layer projected on the substrate by a non-zero distance.
